(19) United States
(12) Patent Application Publication
(10) Pub. No.: US 2006/0238214 A1
(43) Pub. Date: Oct. 26, 2006

(54) Semiconductor circuit, semiconductor device, and method for testing same semiconductor circuit

(75) Inventor: Hiroaki Itoh, Kashihara-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/407,093

(22) Filed: Apr. 20, 2006

(30) Foreign Application Priority Data
Apr. 22, 2005 (JP) 2005-125743

(51) Int. Cl. G01R 31/26

(52) U.S. Cl. 324/765

(57) ABSTRACT

A first diode and a first resistor element are serially connected between a first fixed potential point and a testing terminal. A second diode and a second resistor element are serially connected between a second fixed potential point and the testing terminal. A power supply connected to the testing terminal is set such that the currents to be caused to flow through the first resistor element and the second resistor element are respectively set. With this, the resistance of each of the first and second resistor elements can be measured when a plurality of currents are allowed to separately flow through the resistor element and the other resistor element becomes OFF. Thus, the first resistor element and the second resistor element can be tested with the use of a single testing terminal.

This Nonprovisional application claims priority under 35 U.S.C. § 119(a) on Patent Application No. 125743/2005 filed in Japan on Apr. 22, 2005, the entire contents of which are hereby incorporated by reference.

### FIELD OF THE INVENTION

The present invention relates to a semiconductor circuit for test use, and to a semiconductor device. Particularly, the present invention relates to a semiconductor circuit including a plurality of resistors, to a testing circuit provided in a semiconductor device, and to a testing method.

### BACKGROUND OF THE INVENTION

Conventionally, a semiconductor device provided with a plurality of testing terminals has been widely used so as to test resistors formed on the semiconductor device. Further, there has been a growing demand for a highly functional and high-performance semiconductor device, e.g., integrated circuit in particular. In order to satisfy such a demand, plural types of element are frequently used in appropriate locations in such a semiconductor device, respectively.

A circuit which is required to achieve low current consumption and high sensitivity needs to have a high resistance. On the other hand, a circuit allowing a large current to flow therethrough, or a circuit required to achieve reduction of a current loss needs to have a low resistance. When resistors of one type are used for circuit designing so as to attain such a resistance, the resistors occupy a very large area in the integrated circuit.

In the meanwhile, many types of reference power supply and amplifier employ resistors of plural types. Such resistors are different from one another in terms of accuracy and characteristics. Accordingly, a single semiconductor device employs such plural types of resistors.

In many cases, such resistors are responsible for an important characteristic of the semiconductor device. In view of this, a method for testing the resistors is provided so as to secure a desired performance of a product using the semiconductor device from being deteriorated due to unevenness in manufacturing the resistors. Such a test is carried out with the use of (i) test resistors and (ii) terminals for testing the test resistors, each of which is provided in the semiconductor device. That is, the semiconductor device is tested by measuring the resistances of the test resistors. In this way, the performance of the semiconductor device can be maintained.

FIG. 11 shows an example of a conventional circuit arrangement for testing resistors provided on a semiconductor device.

See FIG. 11. According to a commonly used method, terminals are provided as many as test resistors such that the resistances of the test resistors are measured. However, the method raises such a problem that an increase in the number of resistors causes an increase in the number of terminals. Meanwhile, downsizing of the elements of the integrated circuit has been carried out; however, external connection terminals cannot be downsized as small as the elements due to the mechanical precision and strength of the external connection terminals.

An increase in the number of external connection terminals not only causes an increase in the size of the circuit, but also affects the size and price of the device. Therefore, the number of external connection terminals needs to be reduced as much as possible.

For the purpose of reducing the number of external connection terminals, Japanese Unexamined Patent Publication No. 253718/1998 (Tokukaihei 10-253718; published on Sep. 25, 1998) (Patent Document 1) discloses a testing semiconductor circuit which includes a plurality of testing input terminals and a plurality of testing output terminals. In the testing semiconductor circuit, the test is carried out by turning on and off a switch.

Further, Japanese Unexamined Patent Publication No. 288467/1998 (Tokukaihei 10-288647; published on Oct. 27, 1998) (Patent Document 2) discloses a testing semiconductor circuit which includes an input/output terminal, a change-over switch, and a change-over switch control signal input terminal. In the testing semiconductor circuit, the switch and the input/output terminal are connected via an analog test bus.

### SUMMARY OF THE INVENTION

However, a switching control input terminal for turning on and off a switch provided in a device needs to be newly provided in the conventional arrangement. Further, for measurement of the resistances of two types of resistor, two input terminals are required. In other words, an increase in the number of resistors causes an increase in the number of input terminals. This causes the circuit to be complicated, with the result that the downsizing of the device cannot be expected.

The present invention has been made in view of the foregoing problems. It is an object of the present invention to realize (i) a semiconductor circuit which requires only a small number of external connection terminals for testing two types of resistor, (ii) a semiconductor device, and (ii) a method for testing the semiconductor circuit.

In order to attain the foregoing object, a semiconductor circuit according to the present invention includes: a first fixed potential point; a second fixed potential point; a first switching section; a second switching section; a first resistor element, whose resistance is to be measured; a second resistor element, whose resistance is to be measured; and a testing terminal for measuring the resistance of the first resistor element and the resistance of the second resistor element, the first switching section becoming ON and OFF in accordance with a potential difference applied between the first fixed potential point and the testing terminal, the second switching section becoming ON and OFF in accordance with a potential difference applied between the second fixed potential point and the testing terminal, the first switching section and the first resistor element being serially connected between the first fixed potential point and the testing terminal, the second switching section and the second resistor element being serially connected between the second fixed potential point and the testing terminal.

In order to attain the foregoing object, a semiconductor circuit according to the present invention includes: a first fixed potential point; a second fixed potential point; a first switching section having a control terminal; a second switching section having a control terminal; a first resistor element, whose resistance is to be measured; a second resistor element, whose resistance is to be measured; and a testing terminal for measuring the resistance of the first resistor element and the resistance of the second resistor element, the first switching section becoming ON and OFF in accordance with a potential difference applied between the control terminal of the first switching section and the testing terminal, the second switching section becoming ON and OFF in accordance with a potential difference applied between the control terminal of the second switching section and the testing terminal, the first switching section and the first resistor element being serially connected between the first fixed potential point and the testing terminal, the second switching section and the second resistor element being serially connected between the second fixed potential point and the testing terminal.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 shows Embodiment 1 of the present invention, and is a circuit diagram illustrating a main part of a semiconductor testing circuit which uses a diode as a switching section.

FIG. 2 is a schematic diagram illustrating a method for testing one resistor element of the semiconductor testing circuit which is illustrated in FIG. 1 and which uses the diode as the switching section.

FIG. 3 is a schematic diagram illustrating a method for testing the other resistor element of the semiconductor testing circuit which is illustrated in FIG. 1 and which uses the diode as the switching section.

FIG. 4 shows Embodiment 2 of the present invention, and is a circuit diagram illustrating a main part of a semiconductor testing circuit which uses a plurality of diodes as a switching section.

FIG. 5 shows Embodiment 3 of the present invention, and is a circuit diagram illustrating a main part of a semiconductor testing circuit which uses a transistor as a switching section.

FIG. 6 is a schematic diagram illustrating a method for testing one resistor element of the semiconductor testing circuit which is illustrated in FIG. 5 which uses the transistor as the switching section.

FIG. 7 is a schematic diagram illustrating a method for testing the other resistor element of the semiconductor testing circuit which is illustrated in FIG. 5 which uses the transistor as the switching section.

FIG. 8 shows Embodiment 4 of the present invention, and is a circuit diagram illustrating a main part of a semiconductor testing circuit which uses a plurality of diodes as a voltage dividing element.

FIG. 9 shows Embodiment 5 of the present invention, and is a circuit diagram illustrating a main part of a semiconductor device which includes a semiconductor testing circuit.

FIG. 10 shows Embodiment 6 of the present invention, and is a schematic diagram illustrating a testing method which uses a semiconductor testing circuit.

FIG. 11 is a circuit diagram illustrating a main part of a conventional semiconductor testing circuit.

### DESCRIPTION OF THE EMBODIMENTS

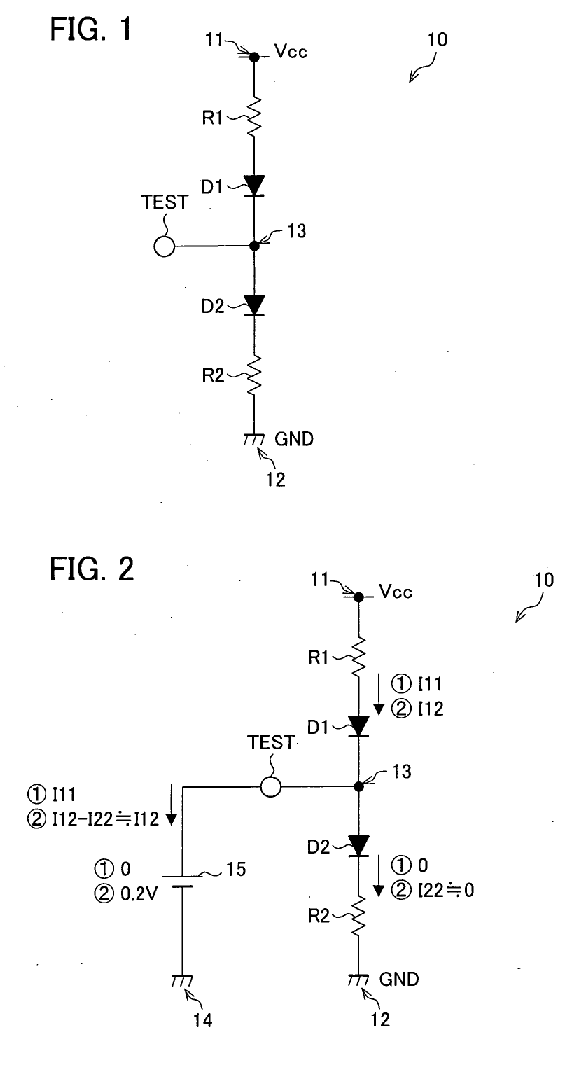

Embodiments of the present invention will be described below with reference to FIGS. 1 through 10.

### Embodiment 1

One embodiment of the present invention will be described below with reference to FIGS. 1 through 3.

FIG. 1 deals with one embodiment of the present invention, and illustrates a circuit arrangement of a semiconductor testing circuit (semiconductor circuit) 10.

The semiconductor testing circuit 10 includes a testing terminal TEST, a first resistor element R1, a second resistor element R2, a first diode (first switching section) D1, a second diode (second switching element) D2, a first fixed potential point 11, a second fixed potential point 12, and a node 13. The semiconductor testing circuit 10 is installed in a semiconductor device, so as to measure the respective actual resistances of (i) a resistor which is used in the semiconductor device and which is manufactured so as to have the same design resistance as the first resistor element R1 and (ii) a resistor which is used in the semiconductor device and which is manufactured so as to have the same design resistance as the second resistor element R2. In other words, each of the first resistor element R1 and the second resistor element R2 is a target resistor element whose resistance is measured with the use of the present invention.

The semiconductor testing circuit 10 is arranged as follows. That is, a power supply Vcc is connected to the first resistor element R1. The first resistor element R1 is connected to an anode of the first diode D1. The first diode D1 has a cathode connected to an anode of the second diode D2. The second diode D2 has a cathode connected to the second resistor element R2. The second resistor element R2 is connected to a ground GND. The testing terminal TEST is connected to the node 13 at which the first diode D1 and the second diode D2 are connected with each other.

The first fixed potential point 11 is connected to both (i) the power supply Vcc having a power supply voltage Vcc, and (ii) the first resistor element R1.

The fixed potential point 12 is connected to both the ground GND and the second resistor element R2.

The testing terminal TEST is a terminal to which an external testing circuit is connected.

The first diode D1 and the second diode D2 operate as the first switching section and the second switching section, respectively. Each of the first and second diodes D1 and D2 has a general property of a diode, i.e., has a property of being conductive in the forward direction in response to application of a voltage of substantially 0.7 V to both the terminals of the diode. Therefore, the following assumes that the first and second diodes D1 and D2 are in an ON state when a forward voltage of substantially 0.7V is applied to the first and second diodes D1 and D2, and that the first and second diodes D1 and D2 are in an OFF state when a forward voltage of less than substantially 0.7 V is applied to the first and second diodes D1 and D2. Note that a small current flows even during the OFF state as described below. Thus, the first and second diodes D1 and D2 are brought to be in the ON state (become ON) in response to application of the forward voltage of substantially 0.7 V, and are brought to be in the OFF state (become OFF) in response to application of the forward voltage of less than substantially 0.7 V.

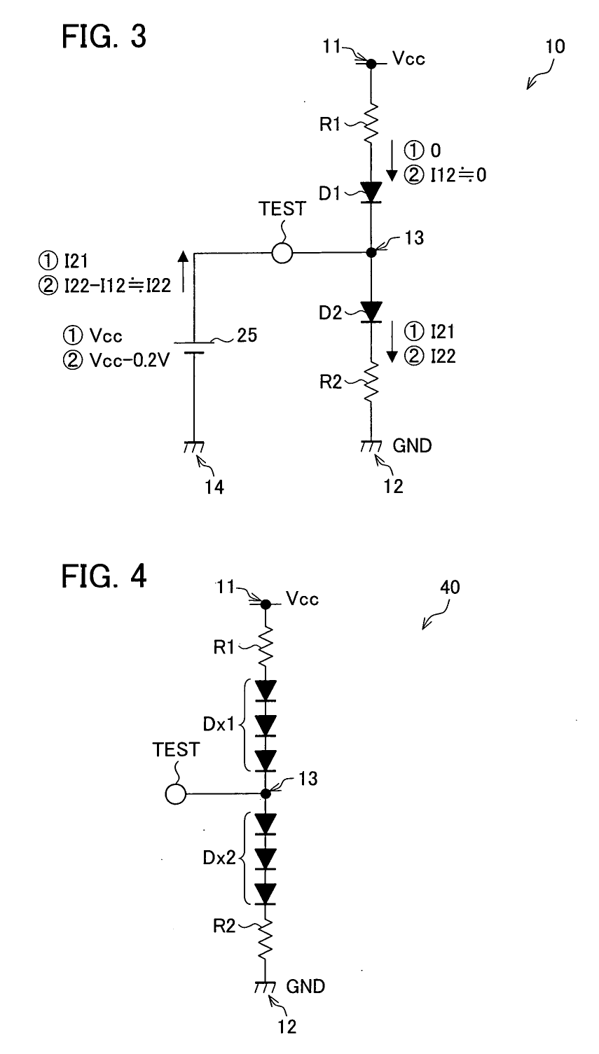

In the following, a method for measuring the respective resistances of the resistor elements with the use of the semiconductor circuit of the present embodiment will be described with reference to FIGS. 2 and 3.

FIG. 2 is a schematic diagram illustrating an arrangement in which a direct-current power supply 15 for generating a constant voltage is connected to the testing terminal TEST of the semiconductor testing circuit 10.

The direct-current power supply 15 is connected to both the testing terminal TEST and a ground 14.

The following explains: Case (1) where no voltage (i.e., a voltage of 0 V) is applied to the direct-current power supply 15 under such conditions that the power supply voltage Vcc is applied to the first fixed potential point 11, and that the second fixed potential point 12 is connected to the ground GND; and Case (2) where a voltage of 0.2 V is applied to the direct-current power supply 15 under the same conditions. Assume that the power supply voltage Vcc is higher than 0.7 V.

Since the voltage applied to the direct-current power supply 15 is 0 V in Case (1), the voltage applied to the testing terminal TEST is 0 V. Moreover, since the voltage applied to the second diode D2 is also 0 V, the second diode D2 is OFF, so that no current flows through the second diode D2.

On the other hand, the first diode D1 is ON, so that a current I11 represented by following formula (1) flows through the first resistor element R1 and the first diode D1:
Vcc=I11·R1+VT·ln(I11/Is) (1)

where VT indicates a thermal voltage kT/q (q: quantity of electric charges of an electron, k: Boltzmann constant, T: absolute temperature), and Is indicates a reverse saturation current of the diode D1.

In this case, no current flows through the second diode D2, so that the current I11 flows from the testing terminal TEST to the direct-current power supply 15.

Now, see Case (2). Since the voltage of 0.2 V is applied to the direct-current power supply 15, a current I12 represented by following formula (2) flows through the first diode D1:
0.2V=I12·R1+VT·ln(I12/Is) (2)

In this case, the second diode D2 is OFF, so that the current I22 flowing through the second diode D2 is so small as to be approximate to 0. Accordingly, a current flowing from the testing terminal TEST to the direct-current power supply 15 is approximate to the current I12. The current flowing from the testing terminal TEST to the direct-current power supply 15 is found by the following formula: I12-I22.

From formulas (1) and (2), following formula (3) is derived:
0.2V=(I11/I12)·R1+VT/ln(I11/I12) (3)

Therefore, the resistance of the first resistor element R1 can be measured by (i) measuring the currents I11 and I12 flowing through the testing terminal TEST, and (ii) substituting the measured currents (values) in formula (3).

In cases where the voltage applied to the testing terminal TEST is 0.2 V, the current I22 represented by following formula (4) flows through the second diode D2:
0.2V=I22·R2+VT·ln(I22/Is) (4)

More accurately, the current flowing out of the testing terminal TEST is a current represented by the following formula: I12−I22 However, the saturation current Is of a silicon P-N junction diode is normally approximately 1×10-15 A. This causes the current I22 to be as extremely small as approximately 2 pA. On the other hand, for example, in cases where the power supply voltage Vcc is 3 V and the first resistor element R1 has a resistance of 1 kΩ, the current I11 is 2.26 mA and the current I12 is 2.06 mA. That is, the currents I11 and I12 are much larger than the current I22. Accordingly, the current flowing out of the testing terminal TEST is approximate to the current I12.

Thus, in the present embodiment, the voltage applied so as to cause the first diode D1 to become ON and cause the second diode D2 to become OFF is such a voltage that the current flowing through the second diode D2 becomes negligibly small as compared with the current flowing through the first diode D1. This makes it possible to accurately calculate the resistance of the first resistor element R1 in particular.

FIG. 3 is a schematic diagram illustrating an arrangement for testing the resistor element R2 of the semiconductor testing device 10. FIG. 3 differs from FIG. 2 in that the direct-current power supply 15 is replaced by a direct-current power supply 25.

The following explains: Case (1) where a voltage Vcc is applied to the direct-current power supply 25 under such conditions that the power supply voltage Vcc is applied to the first fixed potential point 11, and that the second fixed potential point 12 is connected to the ground GND; and Case (2) where a voltage Vcc−0.2 V is applied to the direct-current power supply 25 under the same conditions.

In Case (1), a current I21 flowing from the direct-current power supply 25 into the testing terminal TEST is represented by following formula (5):
Vcc=I21·R2+VT·ln(I21/Is) (5)

In Case 2, the current I22 flowing from the direct-current power supply 25 into the testing terminal TEST is represented by following formula (6):
Vcc−0.2V=I22·R2+VT·ln(I22/Is) (6)

From formulas (5) and (6), following formula (7) is derived:
0.2V=(I21−I22)·R2+VT·ln(I21/I22) (7)

The resistance of the second resistor element R2 can be measured by substituting the currents I21 and I22 in formula (7).

Further, in this case, the voltage applied to the testing terminal so as to cause the first diode D1 to become OFF and cause the second diode D2 to become ON is such a voltage that the current flowing through the first diode D1 becomes negligibly small as compared with the current flowing through the second diode D2. This makes it possible to accurately calculate the resistance of the second resistor element R2 in particular.

The foregoing description assumes that: the voltage of the testing terminal TEST is set with the use of the direct-current power supply 15 such that the resistance of the first resistor element R1 is measured by measuring the current flowing through the testing terminal TEST; and the voltage of the testing terminal TEST is set with the use of the direct-current power supply 25 such that the resistance of the second resistor element R2 is measured by measuring the current flowing through the testing terminal TEST. However, the measurement of the resistances of the first and second resistor elements R1 and R2 is not limited to this. For example, the resistances of the first and second resistor elements R1 and R2 may be measured by measuring the voltage applied to the testing terminal TEST, under such conditions that the current flowing through the testing terminal TEST is set by using a constant current source. Specifically, the setting of the current flowing through the testing terminal TEST is carried out such that one of the first and second diodes D1 and D2 respectively used as the first and second switching sections becomes ON (i.e., is caused to be conductive in the forward direction) and the other becomes OFF. This brings about substantially the same effects, as does the case of using the direct-current power supply 15 and the direct-current power supply 25.

Now, consider the following example. Assume that V1 and V2 indicate the voltages obtained in accordance with the set currents I11 and I12 flowing from the testing terminal TEST to the direct-current power supply 15, respectively. The resistor element R1 can be tested by using following formula (8):
V2−V1=(I11−I12)·R1+VT·ln(I11/I12) (8)

Similarly, the second resistor element R2 can be tested in accordance with the set currents I21 and I22.

However, the diodes can be easily set so as to become ON (so as to become conductive) or so as to become OFF (so as to become non-conductive) in cases where the operation of the first and second switching sections is determined by the voltage applied to the testing terminal TEST, as is the case with the case of using the direct-current power supply 15 and the direct-current power supply 25. This brings about a particularly great effect.

As described above, the semiconductor testing circuit 10 is so arranged as to be a circuit using one testing terminal TEST for separately measuring the resistances of the first and second resistor elements R1 and R2 by respectively setting the currents to be caused to flow through the first and second resistor elements R1 and R2. This allows realization of a resistor testing semiconductor circuit having a small number of external connection terminals. Note that the power supply Vcc and the ground GND of the semiconductor testing circuit 10 may be shared by other circuit sections of the semiconductor device in which the semiconductor testing circuit 10 is installed, with the result that the number of power supply terminals for use in the resistor testing is never increased.

According to the foregoing arrangement, the first diode D1 and the second diode D2 can be used as the first and second switching sections, respectively. This brings about such an effect that the semiconductor circuit of the present invention can be realized using a simple circuit.

### Embodiment 2

Another embodiment of the present invention will be described below with reference to FIG. 4.

The present embodiment is an applied example of Embodiment 1. The present embodiment is arranged in the same manner as the semiconductor testing circuit illustrated in FIGS. 1 through 3, except that each of the first switching section and the second switching section is arranged differently. Components having the same functions as those described in the foregoing embodiment are given the same reference numerals, and description of those components will be omitted.

FIG. 4 deals with the applied example of Embodiment 1. FIG. 4 is a circuit diagram illustrating a semiconductor testing circuit 40 having an arrangement for consuming less power than does the semiconductor testing circuit 10 illustrated in FIG. 1.

As illustrated in FIG. 4, the semiconductor testing circuit 40 of Embodiment 2 is arranged in the following manner. That is, a plurality of diodes Dx1 connected in series in the forward direction replace the first diode D1 illustrated in FIG. 1, so as to be used as the first switching section. Further, a plurality of diodes Dx2 connected in series in the forward direction replace the second diode D2 illustrated in FIG. 1, so as to be used as the second switching section.

In Embodiment 1 illustrated in FIG. 1, a potential difference Vcc is applied between the first fixed potential point 11 and the second fixed potential point 12. Therefore, since the first diode D1, the second diode D2, the first resistor element R1, and the second resistor element R2 are serially connected, a current constantly flows even when the resistances of the first and second resistor elements R1 and R2 are not measured with the use of the semiconductor testing circuit 10. This causes the first and second diodes D1 and D2 and the first and second resistor elements R1 and R2 to generate heat and to consume power.

In Embodiment 1, for example, a current of substantially 788 μA flows in cases where the first and second resistor elements R1 and R2 have resistances of 2 kΩ and the potential difference Vcc applied between the first and second fixed potential points 11 and 12 is 3 V.

In the present embodiment, the plurality of diodes Dx1 are made up of three diodes, each of which is identical to the first diode D1, and which are serially connected. The diodes Dx1 are used as the first switching section. Similarly, the plurality of diodes Dx2 are made up of three diodes, each of which is identical to the second diode D2, and which are serially connected. The diodes Dx2 are used as the second switching section. According to the foregoing arrangement, a current of substantially 0.224 μA flows through the semiconductor testing circuit 40 in cases where the first and second resistor elements R1 and R2 have resistances of 2 kΩ and the potential difference Vcc applied between the first and second fixed potential points 11 and 12 is 3 V.

According to the foregoing arrangement, each of the first switching section and the second switching section is made up of the plurality of diodes (three diodes in the present embodiment), and therefore has a forward voltage three times higher than that of each of the first and second switching sections of Embodiment 1.

As is the case with Embodiment 1, in cases where a direct-current power supply or a constant current source each of which generates a constant voltage is connected to the testing terminal TEST, following formula (9) holds true for the semiconductor testing circuit 40:
0.2V=(I11−I12)·R1+3·VT·ln(I11/I12) (9)

The first and second resistor elements R1 and R2 can be tested in accordance with the formula (9) with the use of the values of the currents I11 and I12, as is the case with Embodiment 1. Moreover, it is possible to greatly reduce power consumed in cases where nothing is connected to the testing terminal TEST.

As described above, according to the foregoing arrangement, only a slight current flows through the testing circuit when nothing is connected to the testing terminal TEST. This brings about an effect of reducing wasteful power consumption.

### Embodiment 3

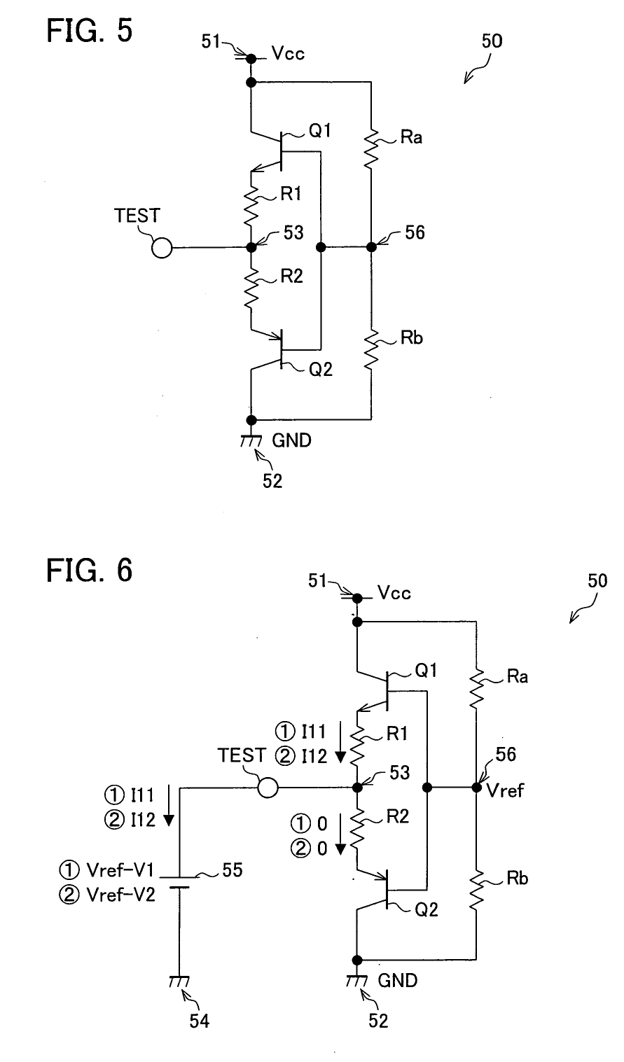

Another embodiment of the present invention will be described below with reference to FIGS. 5 through 7.

FIG. 5 deals with Embodiment 5 of the present invention, and illustrates a circuit arrangement of a semiconductor testing circuit 50.

The semiconductor testing circuit 50 includes: a testing terminal TEST; a first resistor element R1; a second resistor element R2; a resistor element Ra and a resistor element Rb each used for voltage division; a first transistor (first switching section) Q1; a second transistor (second switching section) Q2; a first fixed potential point 51; a second fixed potential point 52; a node 53; and a node 56.

The semiconductor testing circuit 50 is installed in a semiconductor device, so as to measure the respective actual resistances of (i) a resistor which is used in the semiconductor device and which is manufactured so as to have the same design resistance as the first resistor element R1 and (ii) a resistor which is used in the semiconductor device and which is manufactured so as to have the same design resistance as the second resistor element R2. In other words, each of the first resistor element R1 and the second resistor element R2 is a target resistor element whose resistance is measured with the use of the present invention.

The first transistor Q1 is an NPN transistor.

The second transistor Q2 is a PNP transistor.

The first and second transistors Q1 and Q2 are referred to as the first and second switching sections, respectively. When the first and second transistors Q1 and Q2 are in the ON state, the first and second transistors Q1 and Q2 are used so as not to be saturated.

The semiconductor testing circuit 50 is arranged as follows. That is, a power supply Vcc is connected to a collector of the first transistor Q1. The first transistor Q1 has an emitter connected to the first resistor element R1. The first resistor element R1 is connected to the second resistor element R2. The second resistor element R2 is connected to an emitter of the second transistor Q2. The second transistor Q2 has a collector connected to a ground GND. The testing terminal TEST is connected to the node 53 at which the first resistor element R1 and the second resistor element are connected with each other.

Further, in the semiconductor testing circuit 50, the resistor element Ra and the resistor element Rb are connected in this order between the power supply Vcc and the ground GND so as to be parallel to the foregoing circuit arrangement. Respective base terminals of the first and second transistors Q1 and Q2 are connected to the node 56 at which the resistor element Ra and the resistor element Rb are connected with each other. A potential of the node 56 is set in accordance with respective resistances of the resistor elements Ra and Rb so as to be a given voltage (potential) falling within a range between the ground voltage and the power supply voltage Vcc.

The fixed potential point 51 is connected to both (i) the power supply Vcc having a power supply voltage Vcc, and (ii) the first transistor Q1.

The fixed potential point 52 is connected to both the ground GND and the second transistor Q2.

The testing terminal TEST is a terminal to which an external testing circuit is connected, and is connected to the node 53 at which the first resistor element R1 and the second resistor element R2 are connected with each other.

In the foregoing circuit arrangement, a potential Vref applied to the node 56 is represented by following formula (10):
Vref=Vcc·Rb/(Ra+Rb) (10)

Further, as is the case with the diode, in cases where each of the transistors is a silicon junction type transistor, the transistor has such a characteristic that: a base-emitter junction of the transistor becomes conductive in the forward direction in response to application of a voltage of substantially 0.7 V to the emitter and base terminal of the transistor, so that a collector-emitter junction of the transistor becomes conductive. Therefore, the following assumes that: each of the first and second transistors Q1 and Q2 is in the ON state when a forward voltage of substantially 0.7 V is applied to the base-emitter junction of the transistor; and each of the first and second transistors Q1 and Q2 is in the OFF state when a forward voltage of less than substantially 0.7 V is applied to the base-emitter junction of the transistor.

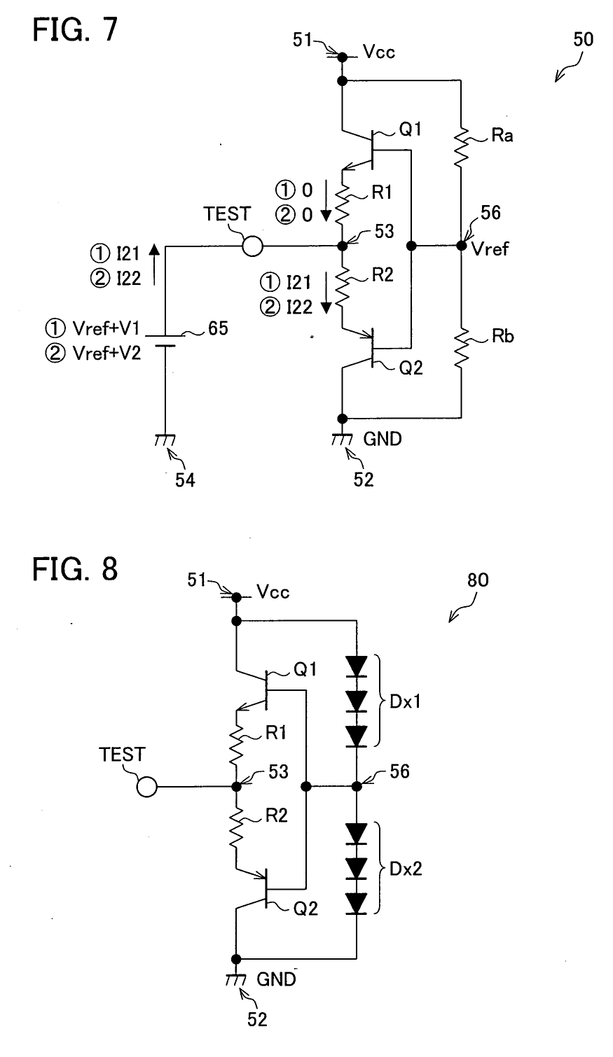

In the following, a method for measuring the respective resistances of the resistor elements with the use of the semiconductor circuit of the present embodiment will be described with reference to FIGS. 6 and 7.

FIG. 6 is a schematic diagram illustrating an arrangement in which the first resistor element R1 is tested under such conditions that a direct-current power supply 55 for generating a constant voltage is connected to the testing terminal TEST of the semiconductor testing device 50.

The direct-current power 55 is connected to both the testing terminal TEST and a ground 54.

In the foregoing circuit arrangement, the potential Vref applied to the node 56 is represented by formula (10) described above.

The following explains: Case (1) where a voltage Vref−V1 is applied from the direct-current power supply 55 to the testing terminal TEST under such conditions that the power supply voltage Vcc is applied to the first fixed potential point 51, and that the second fixed potential point 52 is connected to the ground GND; and Case (2) where a voltage Vref−V2 is applied from the direct-current power supply 55 to the testing terminal TEST under the same conditions.

In Case (1), the potential of the testing terminal TEST is Vref−V1, and the potential of each of the base terminals of the first and second transistors Q1 and Q2 is Vref. Accordingly, a voltage V1 is applied between (i) each of the base terminals of the first and second transistors Q1 and Q2, and (ii) the testing terminal TEST.

In this case, when the voltage V1 is caused to be larger than a forward voltage Vbe applied between the base terminal and emitter of the first transistor Q1, the first transistor Q1 becomes ON and the second transistor Q2 becomes OFF. Now, assume that: a current I11 flows through the first resistor element R1, and the current flowing through the base terminal of the first transistor Q1 is ignored. Then, following formula (11) is found:
V1=I11·R1+VT·ln(I11/Isn) (11)

where VT indicates the thermal voltage, and Isn indicates the reverse saturation voltage of the first transistor Q1.

On the other hand, the voltage V1 is applied in the reverse direction between the base terminal and emitter of the second transistor Q2. This causes the second transistor Q2 to become OFF, so that no current flows through the second resistor element R2. Accordingly, the current flowing from the testing terminal TEST to the direct-current power supply 55 becomes as large as the current I11.

Similarly, in Case (2), the potential of the direct-current power supply 55 is Vref−V2, and the potential of each of the base terminals of the first and second transistors Q1 and Q2 is Vref. Accordingly, a voltage V2 is applied between (i) each of the base terminals of the first and second transistors Q1 and Q2, and (ii) the testing terminal TEST.

In this case, when the voltage V2 is caused to be larger than the forward voltage Vbe applied between the base terminal and emitter of the first transistor Q1, the first transistor Q1 becomes ON and the second transistor Q2 becomes OFF. Now, assume that: a current I12 flows through the first resistor element R1, and the current flowing through the base terminal of the first transistor Q1 is ignored. Then, following formula (12) is found:
V2=I12·R1+VT·ln(I12/Isn) (12)

Accordingly, the current flowing from the testing terminal TEST to the direct-current power supply 55 becomes as large as the current I12.

From formulas (11) and (12), following formula (13) is derived:
V1−V2=(I11−I12)·R1+VT·ln(I11/I12) (13)

The resistance of the first resistor element R1 can be measured by substituting the currents I11 and I12 in formula (13).

FIG. 7 deals with the same arrangement as does FIG. 6, except that the direct-current power supply 55 is replaced by a direct-current power supply 65 for generating a constant voltage. FIG. 7 is a schematic diagram illustrating a state where the second resistor element R2 is tested. Note that description of components identical to those described above will be omitted.

The following explains: Case (1) where a voltage Vref+V1 is applied from the direct-current power supply 65 to the testing terminal TEST under such conditions that the power supply voltage Vcc is applied to the first fixed potential point 51, and that the second fixed potential point 52 is connected to the ground GND; and Case (2) where a voltage Vref+V2 is applied from the direct-current power supply 65 to the testing terminal TEST under the same conditions.

In these cases, the first transistor Q1 becomes OFF and the second transistor Q2 becomes ON.

In Case (1), assume that a current I21 flows from the direct-current power supply 65 into the testing terminal TEST. Then, following formula (14) is found:
V1=I21·R2+VT·ln(I21/Isp) (14)

In Case (2), assume that a current I22 flows from the direct-current power supply 65 into the testing terminal TEST. Then, following formula (15) is found:
V2=I22·R2+VT·ln(I22/Isp) (15)

From formulas (14) and (15), following formula (16) is derived:
V1−V2=(I21−I22)·R2+VT·ln(I21/I22) (16)

The resistance of the second resistor element R2 can be measured by substituting the currents I21 and I22 in formula (16).

The foregoing description assumes that: the voltage of the testing terminal TEST is set with the use of the direct-current power supply 55 such that the resistance of the first resistor element R1 is measured by measuring the current flowing through the testing terminal TEST; and the voltage of the testing terminal TEST is set with the use of the direct-current power supply 65 such that the resistance of the second resistor element R2 is measured by measuring the current flowing through the testing terminal TEST. However, the measurement of the resistances of the first and second resistor elements R1 and R2 is not limited to this. For example, the resistances of the first and second resistor elements R1 and R2 may be measured by measuring the voltage applied to the testing terminal TEST, under such conditions that the current flowing through the testing terminal TEST is set by using a constant current source. Specifically, the setting of the current flowing through the testing terminal TEST is carried out such that one of the first and second transistors Q1 and Q2 respectively used as the first and second switching sections becomes ON and the other becomes OFF. This brings about substantially the same effects, as does the case of using the direct-current power supply 55 and the direct-current power supply 65.

Now, consider the following example. Assume that V1 and V2 indicate the voltages obtained in accordance with the set currents I11 and I12 flowing from the testing terminal TEST to the direct-current power supply 55, respectively. The resistor element R1 can be tested by using formula (8) shown above.

However, the transistors respectively used as the first and second switching sections can be easily set so as to become ON or so as to become OFF in cases where the operation of the first and second switching sections is determined by the voltage applied to the testing terminal TEST, as is the case with the present embodiment. This brings about a particularly great effect.

As described above, according to the semiconductor testing circuit 50 is arranged so as to be a circuit using one testing terminal TEST for separately measuring the resistances of the first and second resistor elements R1 and R2 by respectively setting the currents to be caused to flow through the first and second resistor elements R1 and R2. This allows realization of a resistor testing semiconductor circuit having a small number of external connection terminals. Note that the power supply Vcc and the ground GND of the semiconductor testing circuit 50 may be shared by other circuit sections of the semiconductor device in which the semiconductor testing circuit 50 is installed, with the result that the number of power supply terminals for use in the resistor testing is never increased.

According to the foregoing arrangement, the first transistor Q1 and the second transistor Q2 are used as the first and second switching sections, respectively. This makes it easy to constitute a semiconductor element in cases where a resistor testing semiconductor circuit is provided in a semiconductor device employing a large number of transistors each identical to the first and second transistors Q1 and Q2.

### Embodiment 4

Another embodiment of the present invention will be described below with reference to FIG. 8.

The present embodiment is an applied example of Embodiment 3. The present embodiment is arranged in the same manner as the semiconductor testing circuit 50 illustrated in FIGS. 5 through 7, except that the resistor elements Ra and Rb for dividing the potential applied between the first and second fixed potential points 51 and 52 are replaced by a plurality of diodes Dx1 and a plurality of diodes Dx2, respectively. Components having the same functions as those described in the foregoing embodiment are given the same reference numerals, and description of those components will be omitted.

FIG. 8 deals with the applied example of Embodiment 3. FIG. 8 is a circuit diagram illustrating a semiconductor testing circuit 80 having an arrangement for consuming less power than does the semiconductor testing circuit 50 illustrated in FIG. 5.

As illustrated in FIG. 8, the semiconductor testing circuit 80 of Embodiment 4 is arranged in the following manner. That is, the voltage-dividing resistor element Ra illustrated in FIG. 5 is replaced by the plurality of diodes Dx1 connected in series in the forward direction, and the voltage-dividing resistor element Rb is replaced by the plurality of diodes Dx2 connected in series in the forward direction.

See a case where the semiconductor testing circuit 50 of Embodiment 3 illustrated in FIG. 5 is not tested. In this case, the first transistor Q1 and the second transistor Q2 are in the OFF state as long as nothing is connected to the testing terminal TEST. Therefore, no current flows through the first resistor element R1 and the second resistor element R2. However, a current constantly flows from the first fixed potential point 51 to the second fixed potential point 52 through the resistor elements Ra and Rb for applying a potential to each of the base terminals of the first and second transistors Q1 and Q2.

In Embodiment 3, for example, a current of substantially 150 μA flows in cases where the first and second resistor elements Ra and Rb have resistances of 10 kΩ and the potential difference Vcc applied between the first fixed potential point 51 and the second potential point 52 is 3 V.

In the present embodiment, the plurality of diodes Dx1 are made up of three identical diodes which are serially connected. The diodes Dx1 are used as the resistor element Ra for use in voltage division. Similarly, the plurality of diodes Dx2 are made up of three identical diodes which are serially connected. The diodes Dx2 are used as the resistor element Rb for use in voltage division. According to the foregoing arrangement, a current of substantially 0.225 μA flows through the semiconductor testing circuit 80 in cases where the first and second resistor elements R1 and R2 have resistances of 10 kΩ and the potential difference Vcc applied between the first fixed potential point 51 and the second potential point 52 is 3 V.

With the foregoing arrangement, the present embodiment makes it possible to test the first and second resistor elements R1 and R2 in accordance with the values of the currents I11 and I12, as is the case with Embodiment 3. Moreover, it is possible to greatly reduce power consumed in cases where nothing is connected to the testing terminal TEST.

As described above, according to the foregoing arrangement, only a slight current flows through the testing circuit when nothing is connected to the testing terminal TEST. This brings about an effect of reducing wasteful power consumption.

### Embodiment 5

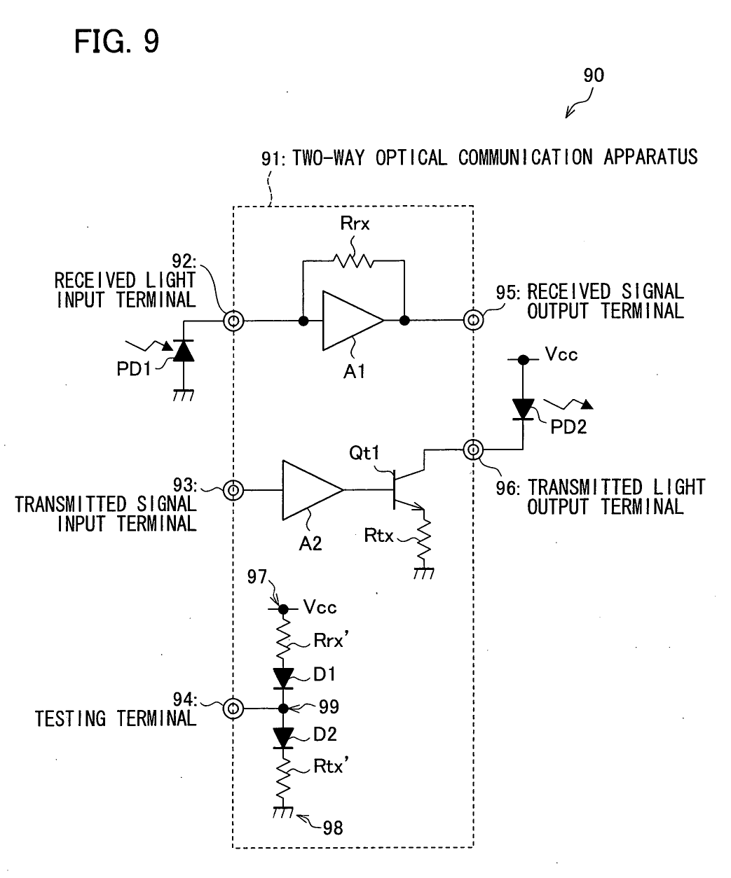

FIG. 9 deals with one embodiment of the present invention, and is a circuit diagram illustrating an arrangement of a main part of a semiconductor device which includes a semiconductor circuit of the present invention.

An optical communication apparatus 90 includes: a two-way optical communication device 91, which is a semiconductor device; and an input/output device connected to an external connection terminal provided in the two-way optical communication device 91.

The two-way optical communication device 91 is provided with the following external connection terminals (1) through (5): (1) a received light input terminal 92 to which a photodiode PD 1 is connected; (2) a transmitted signal input terminal 93 for receiving a transmitted signal; (3) a testing terminal 94 (corresponding to the aforementioned testing terminal TEST) to which a testing power supply is connected; (4) a received signal output terminal 95 for outputting a received signal; and (5) a transmitted light output terminal 96 which is connected to a power supply Vcc via a light-emitting diode PD2.

In the two-way optical communication device 91, an amplifier A1 and a resistor element Rrx are connected in parallel between the received light input terminal 92 and the received signal output terminal 95.

Further, in the two-way optical communication device 91, an amplifier A2 and a transistor Qt1 are provided in this order between the transmitted signal input terminal 93 and the transmitted signal output terminal 96. The transistor Qt1 has a base terminal connected to the amplifier A2, and has a collector connected to the transmitted signal output terminal 96, and has an emitter connected to a ground via a resistor element Rtx.

Further, in the two-way optical communication device 91, a semiconductor circuit of the present invention is connected to the testing terminal 94. The semiconductor circuit is arranged in the same manner as the semiconductor testing circuit 10 of Embodiment 1. That is, a first fixed potential point 97 is connected to a first resistor element Rrx′. The first resistor element Rrx′ is connected to a first diode D1. The first diode D1 is connected to a node 99. The node 99 is connected to a second diode D2. The second diode D2 is connected to a second resistor element Rtx′. The second resistor element Rtx′ is connected to a second fixed potential point 98.

The first resistor element Rrx′ has the same characteristic as the resistor element Rrx, and is provided on the two-way optical communication device 91, and and is a resistor element whose resistance is measured with the use of the semiconductor testing circuit.

The second resistor element Rtx′ has the same characteristic as the resistor element Rtx, and is provided on the two-way optical communication device 91, and is a resistor element whose resistance is measured with the use of the semiconductor testing circuit.

Further, a power supply is connected to the test terminal 94 of the above arrangement such that the first resistor element Rrx′ and the second resistor element Rtx′ are tested in accordance with any one of the methods of the foregoing embodiments. By testing the first resistor element Rrx′ and the second resistor element Rtx′ as such, the resistor elements Rrx and Rtx are tested. In this way, the quality of the entire two-way optical communication device 91 is tested.

As described above, the resistance of each of the first and second resistor elements Rrx′ and Rtx′ is measured in accordance with either (i) respective currents caused to flow through the testing terminal 94 in response to application of two different voltages to the testing terminal 94, or (ii) respective voltages applied to the testing terminal 94 by causing two different currents to flow through the testing terminal 94. This makes it possible to realize a method for testing two resistor elements with the use of a single testing terminal.

Further, the semiconductor testing circuit according to each of Embodiments 2 to 4 may be provided on the two-way optical communication device 91 such that the resistance is measured.

### Embodiment 6

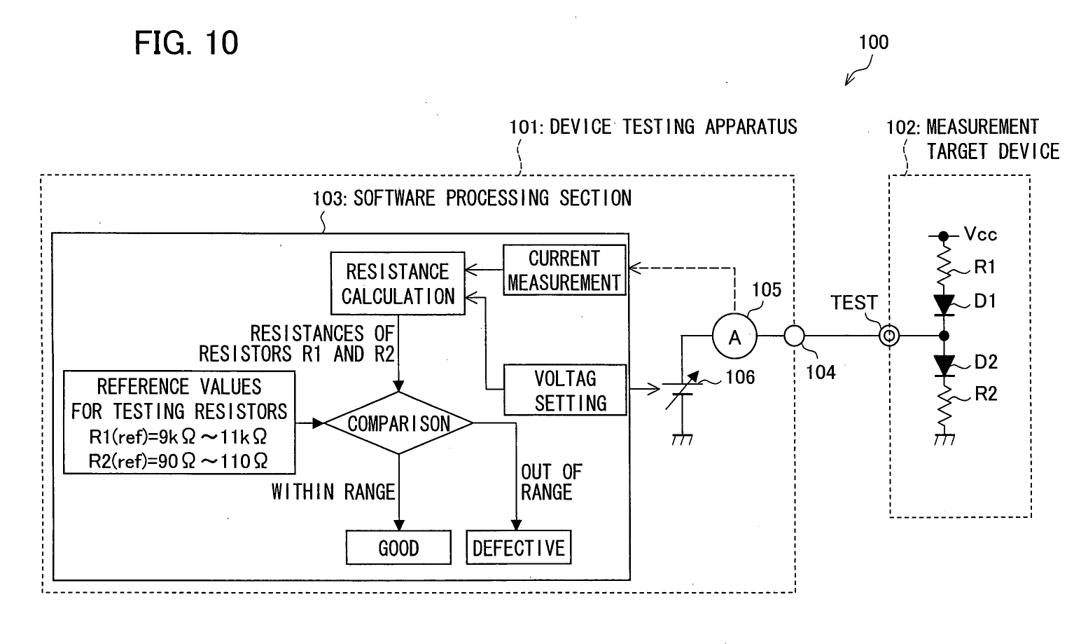

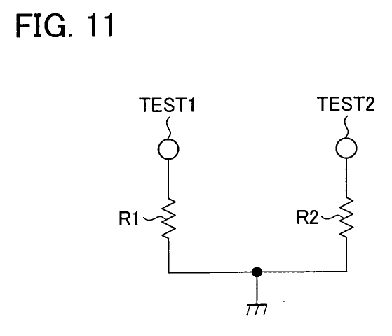

FIG. 10 deals with one embodiment of the present invention, and is a schematic diagram illustrating a testing method which uses a semiconductor circuit of the present invention.

A testing apparatus 100 includes a device testing apparatus 101 and a measurement target device 102.

As is the case with the two-way optical communication device 91 of Embodiment 5, the measurement target device 102 includes a semiconductor testing circuit 10 identical to that of Embodiment 1. Description of components having the same functions as those described in Embodiment 1 will be omitted.

The measurement target device 102 has a testing terminal TEST to which a connection terminal 104 of the device testing apparatus 101 is connected.

The connection terminal 104 is connected to a variable voltage supply 106 via an ammeter 105.

A software processing section 103 controls a voltage set in the variable voltage supply 106, and detects a value indicated by the ammeter 105. The resistance of each of the first and second transistor elements R1 and R2 is measured in accordance with the set voltage and the detected result, and is compared with each of prepared reference values (resistances). In cases where the resistance thus calculated falls within a range of the reference values, the resistor element is judged to be good. In cases where the resistance thus calculated falls out of the reference range, the resistor element is judged to be defective.

In the present embodiment, in cases where the result of measuring the resistance of the first resistor element R1 falls within a range of 9 kΩ to 11 kΩ, the first resistor element R1 is judged to be good. Further, in cases where the result of measuring the resistance of the second resistor element R2 falls within a range of 90Ω to 110Ω, the second resistor element R2 is judged to be good. In accordance with these test results, the quality of the measurement target device 102 is tested.

According to the foregoing arrangement, a method for testing the quality of the measurement target device 102 can be realized by comparing, with the predetermined value, each of the results of measuring the resistances of the first and second resistor elements R1 and R2 are compared with the predetermined value.

As described above, In order to attain the foregoing object, a semiconductor circuit (semiconductor testing circuit 10) according to the present invention includes: a first fixed potential point (first fixed potential point 11); a second fixed potential point (second fixed potential point 12); a first switching section (first diode D1); a second switching section (second diode D2); a first resistor element (first resistor element R1), whose resistance is to be measured; a second resistor element (second resistor element R2), whose resistance is to be measured; and a testing terminal (testing terminal TEST) for measuring the resistance of the first resistor element and the resistance of the second resistor element, the first switching section becoming ON and OFF in accordance with a potential difference applied between the first fixed potential point and the testing terminal, the second switching section becoming ON and OFF in accordance with a potential difference applied between the second fixed potential point and the testing terminal, the first switching section and the first resistor element being serially connected between the first fixed potential point and the testing terminal, the second switching section and the second resistor element being serially connected between the second fixed potential point and the testing terminal.

According to the foregoing arrangement, the use of the first and second switching sections operated in accordance with a setting of a power supply connected to the testing terminal makes it possible to carry out switching between (i) a circuit arrangement in which a current flows through only the first resistor element, and (ii) a circuit arrangement in which a current flows through only the second resistor element. With this, the resistance of one of the first and second resistor elements can be measured when a plurality of currents are allowed to separately flow through the resistor element and the other resistor element becomes OFF. This makes it possible to constitute a circuit using one testing terminal for separately measuring the respective resistances of resistor elements.

This brings about an effect of realizing a semiconductor circuit which requires only a small number of external connection terminals for testing two types of resistor.

As described above, the semiconductor circuit of the present invention is arranged such that: the first switching section and the second switching section are diodes, respectively, and are connected with each other such that respective forward directions of the first switching section and the second switching section are oriented toward either the first fixed potential point or the second fixed potential point.

According to the foregoing arrangement, the switching sections can be constituted using the diodes, respectively. This brings about such an effect that the semiconductor circuit of the present invention can be realized using a simple circuit.

The semiconductor circuit of the present invention is arranged such that: a plurality of diodes connected in series serve as each of the first switching section and the second switching section; and a total of respective forward voltages of the plurality of diodes connected in series is greater than a potential difference applied between the first fixed potential point and the second fixed potential point.

According to the foregoing arrangement, each of the diodes does not become conductive in the forward direction when nothing is connected to the testing terminal TEST. Therefore, only a slight current flows through the testing circuit. This brings about an effect of reducing wasteful power consumption.

As described above, a semiconductor circuit (semiconductor testing circuit 50) according to the present invention includes: a first fixed potential point (first fixed potential point 51); a second fixed potential point (second fixed potential point 52); a first switching section (first transistor Q1) having a control terminal; a second switching section (second transistor Q2) having a control terminal; a first resistor element, whose resistance is to be measured; a second resistor element, whose resistance is to be measured; and a testing terminal for measuring the resistance of the first resistor element and the resistance of the second resistor element, the first switching section becoming ON and OFF in accordance with a potential difference applied between the control terminal of the first switching section and the testing terminal, the second switching section becoming ON and OFF in accordance with a potential difference applied between the control terminal of the second switching section and the testing terminal, the first switching section and the first resistor element being serially connected between the first fixed potential point and the testing terminal, the second switching section and the second resistor element being serially connected between the second fixed potential point and the testing terminal.

According to the foregoing arrangement, the use of the first and second switching sections operated in accordance with a setting of a power supply connected to the testing terminal makes it possible to carry out switching between (i) a circuit arrangement in which a current flows through only the first resistor element, and (ii) a circuit arrangement in which a current flows through only the second resistor element. Each of the first and second switching sections is an element having a characteristic of becoming ON and OFF in accordance with an input supplied to a control terminal of the element. With this, the resistance of one of the first and second resistor elements can be measured when a plurality of currents are allowed to separately flow through the resistor element and the other resistor element becomes OFF. This makes it possible to constitute a circuit using one testing terminal for separately measuring the respective resistances of resistor elements.

This brings about an effect of realizing a semiconductor circuit which requires only a small number of external connection terminals for testing two types of resistor.

The semiconductor circuit of the present invention further includes: a third fixed potential point, whose potential is determined in accordance with respective potentials of the first fixed potential point and the second fixed potential point, wherein: the first resistor element is provided between the first switching section and the testing terminal; and the second resistor element is provided between the second switching section and the testing terminal; and the third fixed potential point is connected to each of the control terminals of the first switching section and the second switching section.

According to the foregoing arrangement, each of the first and second switching sections is a transistor whose base terminal is used as a control terminal of the switching section. The transistor can be switched ON or OFF depending on whether a base-emitter junction of the transistor is ON or OFF. This brings about such an effect of making it easy to constitute a semiconductor element particularly in a semiconductor circuit using a large number of transistors identical to the transistor.

As described above, the semiconductor circuit of the present invention is arranged such that: the first fixed potential point has a higher potential than the second fixed potential point does; and the first switching section is an NPN transistor whose collector is connected to the first fixed potential point and whose emitter is connected to the first resistor element; and the second switching section is a PNP transistor whose collector is connected to the second fixed potential point and whose emitter is connected to the second resistor element; and the NPN transistor and the PNP transistor respectively have base terminals connected to the third fixed potential point.

According to the foregoing arrangement, the first and second switching sections can be constituted using the NPN transistor and the PNP transistor, respectively. This brings about such an effect that a semiconductor testing circuit can be realized by using a simple circuit employing transistors.

As described above, the semiconductor circuit of the present invention further includes: a plurality of diodes, which are serially connected with each other such that each of forward directions of the diodes corresponds to a direction from a high potential side to a low potential side, so that a potential of the third fixed potential point is determined by dividing respective voltages of the first fixed potential point and the second fixed potential point, wherein: a total of respective forward voltages of the diodes is greater than a potential difference applied between the first fixed potential point and the second fixed potential point.

According to the foregoing arrangement, only a slight current flows through the diodes for use in voltage division. This brings about an effect of reducing power wastefully consumed in the entire circuit.

As described above, a semiconductor device having a small number of external connection terminals can be realized by using a semiconductor circuit of the present invention.

As described above, a method for testing a semiconductor circuit of the present invention includes the steps of: testing the first resistor element by measuring the resistance of the first resistor element in accordance with a first current and a second current, the first current being caused to flow through the testing terminal by applying a first voltage to the testing terminal (testing terminal TEST) such that the first switching section (first diode D1) is turned ON and the second switching section (second diode D2) is turned OFF, the second current being caused to flow through the testing terminal by applying a second voltage to the testing terminal such that the first switching section is turned ON and the second switching section is turned OFF, the first voltage and the second voltage being different from each other; and testing the second resistor element by measuring the resistance of the second resistor element in accordance with a third current and a fourth current, the third current being caused to flow through the testing terminal by applying a first voltage to the testing terminal such that the second switching section is turned ON and the first switching section is turned OFF, the fourth current being caused to flow through the testing terminal by applying a fourth voltage to the testing terminal such that the second switching section is turned ON and the first switching section is turned OFF, the third voltage and the fourth voltage being different from each other.

According to the foregoing arrangement, the resistance of each of the first and second resistor elements is measured in accordance with respective currents caused to flow through the testing terminal in response to application of two different voltages is applied to the testing terminal. This makes it possible to realize a method for testing two resistor elements with the use of a single testing terminal.

As described above, a method for testing a semiconductor circuit of the present invention includes the steps of: testing the first resistor element by measuring the resistance of the first resistor element in accordance with a first voltage and a second voltage, the first voltage being applied to the testing terminal by causing a first current to flow through the testing terminal such that the first switching section is turned ON and the second switching section is turned OFF, the second voltage being applied to the testing terminal by causing a second current to flow through the testing terminal such that the first switching section is turned ON and the second switching section is turned OFF, the first current and the second current being different from each other; and testing the second resistor element by measuring the resistance of the second resistor element in accordance with a third voltage and a fourth voltage, the third voltage being applied to the testing terminal by causing a third current to flow through the testing terminal such that the second switching section is turned ON and the first switching section is turned OFF, the fourth voltage being applied to the testing terminal by causing a fourth current to flow through the testing terminal such that the second switching section is turned ON and the first switching section is turned OFF, the third current and the fourth current being different from each other.

According to the foregoing arrangement, the resistance of each of the first and second resistor elements can be measured in accordance with respective voltages applied to the testing terminal by causing two different currents to flow through the testing terminal. This makes it possible to realize a method for testing two resistor elements with the use of a single testing terminal.

The method of the present invention is arranged such that: a resistor element of a semiconductor device including the semiconductor circuit is tested by testing the first resistor element and the second resistor element by making a comparison between (i) a result of measuring the resistance of each of the first resistor element and the second resistor element, and (ii) a predetermined value.

According to the foregoing arrangement, the quality of the entire semiconductor device including the semiconductor circuit using the resistor elements can be tested by using the results of measuring the resistances of the resistor elements.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

For example, the device testing apparatus 101 and the software processing section 103 each of which is included in the testing apparatus 100 may be constituted by hardware logic, or by software with the use of a CPU as follows.

That is, the testing apparatus 100 That is, the present system has: (i) the CPU for executing an instruction of control program realizing various functions; (ii) a ROM storing the program; (iii) a RAM for expanding the program; (iv) a storage device (storage medium) such as a memory storing the program and various data; and (v) the like. The object of the present invention also can be achieved by (i) providing, for the present system, a storage medium storing, in a computer readable manner, a program code (executable program; intermediate code; source program) of the control program for the present system, and (ii) causing a computer (CPU or MPU) to read and execute the program code stored in the storage medium, the program code being the software realizing the aforementioned functions.

Examples of the storage medium are: (i) tapes such as a magnetic tape and a cassette tape; (ii) magnetic disks such as a hard disk and a flexible disk; (iii) optical disks such as a CD-ROM (compact disk read only memory), a magnetic optical disk (MO), a mini disk (MD), a digital video disk (DVD), and a CD-R (CD-Rewritable); (iv) cards such as an IC card (inclusive of a memory card) and an optical card; and (v) semiconductor memories such as a mask ROM, an EPROM (electrically programmable read only memory), an EEPROM (electrically erasable programmable read only memory), and a flash ROM.

Further, the testing apparatus 100 may be connectable to the communication network, and the program code may be supplied via the communication network. The communication network is not particularly limited. Specific examples thereof are: the Internet, Intranet, Extranet, LAN (local area network), ISDN (integrated services digital network), VAN (value added network), CATV (cable TV) communication network, virtual private network, telephone network, mobile communication network, satellite communication network, and the like. Further, the transmission medium constituting the communication network is not particularly limited. Specific examples thereof are: (i) a wired channel using an IEEE 1394, a USB (universal serial bus), a power-line communication, a cable TV line, a telephone line, an ADSL line, or the like; or (ii) a wireless communication using IrDA, infrared rays used for a remote controller, Bluetooth®, IEEE 802.11, HDR (High Data Rate), a mobile phone network, a satellite connection, a terrestrial digital network, or the like. Note that, the present invention can be realized by (i) a carrier wave realized by electronic transmission of the program code, or (ii) a form of a series of data signals.

According to a circuit of the present invention, the use of a single testing terminal makes it possible to carry out switching between (i) a circuit arrangement in which a current flows through a first resistor element, and (ii) a circuit arrangement in which a current flows through a second resistor element. Therefore, the resistances of the first and second resistor elements can be measured separately with the use of the single testing terminal. This allows realization of a semiconductor testing circuit having a small number of external connection terminals. Therefore, the present invention can be applied suitably to semiconductor testing circuits of various types of semiconductor device.

What is claimed:

1. A semiconductor circuit, comprising:
a first fixed potential point;
a second fixed potential point;
a first switching section;
a second switching section;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the first fixed potential point and the testing terminal,
the second switching section becoming ON and OFF in accordance with a potential difference applied between the second fixed potential point and the testing terminal,
the first switching section and the first resistor element being serially connected between the first fixed potential point and the testing terminal,
the second switching section and the second resistor element being serially connected between the second fixed potential point and the testing terminal.

2. The semiconductor circuit as set forth in claim 1, wherein the first switching section and the second switching section are diodes, respectively, and are connected with each other such that respective forward directions of the first switching section and the second switching section are oriented toward either the first fixed potential point or the second fixed potential point.

3. The semiconductor circuit as set forth in claim 2, wherein:
a plurality of diodes connected in series serve as each of the first switching section and the second switching section; and
a total of respective forward voltages of the diodes connected in series is greater than a potential difference applied between the first fixed potential point and the second fixed potential point.

4. A semiconductor circuit, comprising:
a first fixed potential point;
a second fixed potential point;
a first switching section having a control terminal;
a second switching section having a control terminal;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the control terminal of the first switching section and the testing terminal,
the second switching section becoming ON and OFF in accordance with a potential difference applied between the control terminal of the second switching section and the testing terminal,
the first switching section and the first resistor element being serially connected between the first fixed potential point and the testing terminal,
the second switching section and the second resistor element being serially connected between the second fixed potential point and the testing terminal.

5. The semiconductor circuit as set forth in claim 4, further comprising:
a third fixed potential point, whose potential is determined in accordance with respective potentials of the first fixed potential point and the second fixed potential point,
wherein:
the first resistor element is provided between the first switching section and the testing terminal; and
the second resistor element is provided between the second switching section and the testing terminal; and
the third fixed potential point is connected to each of the control terminals of the first switching section and the second switching section.

6. The semiconductor circuit as set forth in claim 5, wherein:
the first fixed potential point has a higher potential than the second fixed potential point does; and
the first switching section is an NPN transistor whose collector is connected to the first fixed potential point and whose emitter is connected to the first resistor element; and
the second switching section is a PNP transistor whose collector is connected to the second fixed potential point and whose emitter is connected to the second resistor element; and
the NPN transistor and the PNP transistor respectively have base terminals connected to the third fixed potential point.

7. The semiconductor circuit as set forth in claim 5, further comprising:
a plurality of diodes, which are serially connected with each other such that each of forward directions of the diodes corresponds to a direction from a high potential side to a low potential side, so that a potential of the third fixed potential point is determined by dividing respective voltages of the first fixed potential point and the second fixed potential point,
wherein:
a total of respective forward voltages of the diodes is greater than a potential difference applied between the first fixed potential point and the second fixed potential point.

8. A semiconductor device, comprising a semiconductor circuit which includes:
a first fixed potential point;
a second fixed potential point;
a first switching section;
a second switching section;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the first fixed potential point and the testing terminal,
the second switching section becoming ON and OFF in accordance with a potential difference applied between the second fixed potential point and the testing terminal,
the first switching section and the first resistor element being serially connected between the first fixed potential point and the testing terminal,
the second switching section and the second resistor element being serially connected between the second fixed potential point and the testing terminal.

9. A semiconductor device, comprising a semiconductor circuit which includes:
a first fixed potential point;
a second fixed potential point;
a first switching section having a control terminal;
a second switching section having a control terminal;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the control terminal of the first switching section and the testing terminal,
the second switching section becoming ON and OFF in accordance with a potential difference applied between the control terminal of the second switching section and the testing terminal,
the first switching section and the first resistor element being serially connected between the first fixed potential point and the testing terminal,
the second switching section and the second resistor element being serially connected between the second fixed potential point and the testing terminal.

10. A method for testing a semiconductor circuit which includes:
a first fixed potential point;
a second fixed potential point;
a first switching section;
a second switching section;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the first fixed potential point and the testing terminal,
the second switching section becoming ON and OFF in accordance with a potential difference applied between the second fixed potential point and the testing terminal,
the first switching section and the first resistor element being serially connected between the first fixed potential point and the testing terminal,
the second switching section and the second resistor element being serially connected between the second fixed potential point and the testing terminal,
the method, comprising the steps of:
testing the first resistor element by measuring the resistance of the first resistor element in accordance with a first current and a second current, the first current being caused to flow through the testing terminal by applying a first voltage to the testing terminal such that the first switching section is turned ON and the second switching section is turned OFF, the second current being caused to flow through the testing terminal by applying a second voltage to the testing terminal such that the first switching section is turned ON and the second switching section is turned OFF, the first voltage and the second voltage being different from each other; and
testing the second resistor element by measuring the resistance of the second resistor element in accordance with a third current and a fourth current, the third current being caused to flow through the testing terminal by applying a third voltage to the testing terminal such that the second switching section is turned ON and the first switching section is turned OFF, the fourth current being caused to flow through the testing terminal by applying a fourth voltage to the testing terminal such that the second switching section is turned ON and the first switching section is turned OFF, the third voltage and the fourth voltage being different from each other.

11. A method for testing a semiconductor circuit which includes:
a first fixed potential point;
a second fixed potential point;
a first switching section;
a second switching section;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the first fixed potential point and the testing terminal,
the second switching section becoming ON and OFF out in accordance with a potential difference applied between the second fixed potential point and the testing terminal,
the first switching section and the first resistor element being serially connected between the first fixed potential point and the testing terminal,
the second switching section and the second resistor element being serially connected between the second fixed potential point and the testing terminal,
the method, comprising the steps of:
testing the first resistor element by measuring the resistance of the first resistor element in accordance with a first voltage and a second voltage, the first voltage being applied to the testing terminal by causing a first current to flow through the testing terminal such that the first switching section is turned ON and the second switching section is turned OFF, the second voltage being applied to the testing terminal by causing a second current to flow through the testing terminal such that the first switching section is turned ON and the second switching section is turned OFF, the first current and the second current being different from each other; and
testing the second resistor element by measuring the resistance of the second resistor element in accordance with a third voltage and a fourth voltage, the third voltage being applied to the testing terminal by causing a third current to flow through the testing terminal such that the second switching section is turned ON and the first switching section is turned OFF, the fourth voltage being applied to the testing terminal by causing a fourth current to flow through the testing terminal such that the second switching section is turned ON and the first switching section is turned OFF, the third current and the fourth current being different from each other.

12. A method for testing a semiconductor circuit which includes:
a first fixed potential point;
a second fixed potential point;
a first switching section having a control terminal;
a second switching section having a control terminal;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the control terminal of the first switching section and the testing terminal,
the second switching section becoming ON and OFF in accordance with a potential difference applied between the control terminal of the second switching section and the testing terminal,
the first switching section and the first resistor element being serially connected between the first fixed potential point and the testing terminal,
the second switching section and the second resistor element being serially connected between the second fixed potential point and the testing terminal,
the method, comprising the steps of:
testing the first resistor element by measuring the resistance of the first resistor element in accordance with a first current and a second current, the first current being caused to flow through the testing terminal by applying a first voltage to the testing terminal such that the first switching section is turned ON and the second switching section is turned OFF, the second current being caused to flow through the testing terminal by applying a second voltage to the testing terminal such that the first switching section is turned ON and the second switching section is turned OFF, the first voltage and the second voltage being different from each other; and
testing the second resistor element by measuring the resistance of the second resistor element in accordance with a third current and a fourth current, the third current being caused to flow through the testing terminal by applying a first voltage to the testing terminal such that the second switching section is turned ON and the first switching section is turned OFF, the fourth current being caused to flow through the testing terminal by applying a fourth voltage to the testing terminal such that the second switching section is turned ON and the first switching section is turned OFF, the third voltage and the fourth voltage being different from each other.

13. A method for testing a semiconductor circuit which includes:
a first fixed potential point;
a second fixed potential point;
a first switching section having a control terminal;
a second switching section having a control terminal;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the control terminal of the first switching section and the testing terminal,
the second switching section becoming ON and OFF in accordance with a potential difference applied between the control terminal of the second switching section and the testing terminal,
the first switching section and the first resistor element being serially connected between the first fixed potential point and the testing terminal,
the second switching section and the second resistor element being serially connected between the second fixed potential point and the testing terminal,
the method, comprising the steps of:
testing the first resistor element by measuring the resistance of the first resistor element in accordance with a first voltage and a second voltage, the first voltage being applied to the testing terminal by causing a first current to flow through the testing terminal such that the first switching section is turned ON and the second switching section is turned OFF, the second voltage being applied to the testing terminal by causing a second current to flow through the testing terminal such that the first switching section is turned ON and the second switching section is turned OFF, the first current and the second current being different from each other; and
testing the second resistor element by measuring the resistance of the second resistor element in accordance with a third voltage and a fourth voltage, the third voltage being applied to the testing terminal by causing a third current to flow through the testing terminal such that the second switching section is turned ON and the first switching section is turned OFF, the fourth voltage being applied to the testing terminal by causing a fourth current to flow through the testing terminal such that the second switching section is turned ON and the first switching section is turned OFF, the third current and the fourth current being different from each other.

14. The method as set forth in claim 10, wherein a resistor element of a semiconductor device including the semiconductor circuit is tested by testing the first resistor element and the second resistor element by making a comparison between (i) a result of measuring the resistance of each of the first resistor element and the second resistor element, and (ii) a predetermined value.

15. The method as set forth in claim 11, wherein a resistor element of a semiconductor device including the semiconductor circuit is tested by testing the first resistor element and the second resistor element by making a comparison between (i) a result of measuring the resistance of each of the first resistor element and the second resistor element, and (ii) a predetermined value.

16. The method as set forth in claim 12, wherein a resistor element of a semiconductor device including the semiconductor circuit is tested by testing the first resistor element and the second resistor element by making a comparison between (i) a result of measuring the resistance of each of the first resistor element and the second resistor element, and (ii) a predetermined value.

17. The method as set forth in claim 13, wherein a resistor element of a semiconductor device including the semiconductor circuit is tested by testing the first resistor element and the second resistor element by making a comparison between (i) a result of measuring the resistance of each of the first resistor element and the second resistor element, and (ii) a predetermined value.

18. A program for testing a semiconductor circuit which includes:
a first fixed potential point;
a second fixed potential point;
a first switching section;
a second switching section;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the first fixed potential point and the testing terminal,
the second switching section becoming ON and OFF in accordance with a potential difference applied between the second fixed potential point and the testing terminal,
the first switching section and the first resistor element being serially connected between the first fixed potential point and the testing terminal,
the second switching section and the second resistor element being serially connected between the second fixed potential point and the testing terminal,
the program, causing a computer to carry out the steps of:
testing the first resistor element by measuring the resistance of the first resistor element in accordance with a first current and a second current, the first current being caused to flow through the testing terminal by applying a first voltage to the testing terminal such that the first switching section is turned ON and the second switching section is turned OFF, the second current being caused to flow through the testing terminal by applying a second voltage to the testing terminal such that the first switching section is turned ON and the second switching section is turned OFF, the first voltage and the second voltage being different from each other; and
testing the second resistor element by measuring the resistance of the second resistor element in accordance with a third current and a fourth current, the third current being caused to flow through the testing terminal by applying a first voltage to the testing terminal such that the second switching section is turned ON and the first switching section is turned OFF, the fourth current being caused to flow through the testing terminal by applying a fourth voltage to the testing terminal such that the second switching section is turned ON and the first switching section is turned OFF, the third voltage and the fourth voltage being different from each other.

19. A program for testing a semiconductor circuit which includes:
a first fixed potential point;
a second fixed potential point;
a first switching section;
a second switching section;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the first fixed potential point and the testing terminal,
the second switching section becoming ON and OFF in accordance with a potential difference applied between the second fixed potential point and the testing terminal,
the first switching section and the first resistor element being serially connected between the first fixed potential point and the testing terminal,
the second switching section and the second resistor element being serially connected between the second fixed potential point and the testing terminal,
the program, causing a computer to carry out the steps of:
testing the first resistor element by measuring the resistance of the first resistor element in accordance with a first voltage and a second voltage, the first voltage being applied to the testing terminal by causing a first current to flow through the testing terminal such that the first switching section is turned ON and the second switching section is turned OFF, the second voltage being applied to the testing terminal by causing a second current to flow through the testing terminal such that the first switching section is turned ON and the second switching section is turned OFF, the first current and the second current being different from each other; and
testing the second resistor element by measuring the resistance of the second resistor element in accordance with a third voltage and a fourth voltage, the third voltage being applied to the testing terminal by causing a third current to flow through the testing terminal such that the second switching section is turned ON and the first switching section is turned OFF, the fourth voltage being applied to the testing terminal by causing a fourth current to flow through the testing terminal such that the second switching section is turned ON and the first switching section is turned OFF, the third current and the fourth current being different from each other.

20. A program for testing a semiconductor circuit which includes:
a first fixed potential point;
a second fixed potential point;
a first switching section having a control terminal;
a second switching section having a control terminal;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the control terminal of the first switching section and the testing terminal,
the second switching section becoming ON and OFF in accordance with a potential difference applied between the control terminal of the second switching section and the testing terminal,
the first switching section and the first resistor element being serially connected between the first fixed potential point and the testing terminal,
the second switching section and the second resistor element being serially connected between the second fixed potential point and the testing terminal,
the program, causing a computer to carry out the steps of:
testing the first resistor element by measuring the resistance of the first resistor element in accordance with a first current and a second current, the first current being caused to flow through the testing terminal by applying a first voltage to the testing terminal such that the first switching section is turned ON and the second switching section is turned OFF, the second current being caused to flow through the testing terminal by applying a second voltage to the testing terminal such that the first switching section is turned ON and the second switching section is turned OFF, the first voltage and the second voltage being different from each other; and
testing the second resistor element by measuring the resistance of the second resistor element in accordance with a third current and a fourth current, the third current being caused flow through the testing terminal by applying a first voltage to the testing terminal such that the second switching section is turned ON and the first switching section is turned OFF the fourth current being caused to flow through the testing terminal by applying a fourth voltage to the testing terminal such that the second switching section is turned ON and the first switching section is turned OFF, the first voltage and the second voltage being different from each other.

21. A program for testing a semiconductor circuit which includes:
a first fixed potential point;
a second fixed potential point;
a first switching section having a control terminal;
a second switching section having a control terminal;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the control terminal of the first switching section and the testing terminal,
the second switching section becoming ON and OFF in accordance with a potential difference applied between the control terminal of the second switching section and the testing terminal,
the first switching section and the first resistor element being serially connected between the first fixed potential point and the testing terminal,
the second switching section and the second resistor element being serially connected between the second fixed potential point and the testing terminal,
the program, causing a computer to carry out the steps of:
testing the first resistor element by measuring the resistance of the first resistor element in accordance with a first voltage and a second voltage, the first voltage being applied to the testing terminal by causing a first current to flow through the testing terminal such that the first switching section is turned ON and the second switching section is turned OFF, the second voltage being applied to the testing terminal by causing a second current to flow through the testing terminal such that the first switching section is turned ON and the second switching section is turned OFF, the first current and the second current being different from each other; and
testing the second resistor element by measuring the resistance of the second resistor element in accordance with a third voltage and a fourth voltage, the third voltage being applied to the testing terminal by causing a third current to flow through the testing terminal such that the second switching section is turned ON and the first switching section is turned OFF, the fourth voltage being applied to the testing terminal by causing a fourth current to flow through the testing terminal such that the second switching section is turned ON and the first switching section is turned OFF, the third current and the fourth current being different from each other.

22. A storage medium storing a program for testing a semiconductor circuit which includes:
a first fixed potential point;
a second fixed potential point;
a first switching section;
a second switching section;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the first fixed potential point and the testing terminal,
the second switching section becoming ON and OFF in accordance with a potential difference applied between the second fixed potential point and the testing terminal,
the first switching section and the first resistor element being serially connected between the first fixed potential point and the testing terminal,
the second switching section and the second resistor element being serially connected between the second fixed potential point and the testing terminal,
the program, causing a computer to carry out the steps of:
testing the first resistor element by measuring the resistance of the first resistor element in accordance with a first current and a second current, the first current being caused to flow through the testing terminal by applying a first voltage to the testing terminal such that the first switching section is turned ON and the second switching section is turned OFF, the second current being caused to flow through the testing terminal by applying a second voltage to the testing terminal such that the first switching section is turned ON and the second switching section is turned OFF, the first voltage and the second voltage being different from each other; and
testing the second resistor element by measuring the resistance of the second resistor element in accordance with a third current and a fourth current, the third current being caused to flow through the testing terminal by applying a first voltage to the testing terminal such that the second switching section is turned ON and the first switching section is turned OFF, the fourth current being caused to flow through the testing terminal by applying a fourth voltage to the testing terminal such that the second switching section is turned ON and the first switching section is turned OFF, the third voltage and the fourth voltage being different from each other.

23. A storage medium storing a program for testing a semiconductor circuit which includes:
a first fixed potential point;
a second fixed potential point;
a first switching section;
a second switching section;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the first fixed potential point and the testing terminal,
the second switching section becoming ON and OFF in accordance with a potential difference applied between the second fixed potential point and the testing terminal,
the first switching section and the first resistor element being serially connected between the first fixed potential point and the testing terminal,
the second switching section and the second resistor element being serially connected between the second fixed potential point and the testing terminal,
the program, causing a computer to carry out the steps of:
testing the first resistor element by measuring the resistance of the first resistor element in accordance with a first voltage and a second voltage, the first voltage being applied to the testing terminal by causing a first current to flow through the testing terminal such that the first switching section is turned ON and the second switching section is turned OFF, the second voltage being applied to the testing terminal by causing a second current to flow through the testing terminal such that the first switching section is turned ON and the second switching section is turned OFF, the first current and the second current being different from each other; and
testing the second resistor element by measuring the resistance of the second resistor element in accordance with a third voltage and a fourth voltage, the third voltage being applied to the testing terminal by causing a third current to flow through the testing terminal such that the second switching section is turned ON and the first switching section is turned OFF, the fourth voltage being applied to the testing terminal by causing a fourth current to flow through the testing terminal such that the second switching section is turned ON and the first switching section is turned OFF, the third current and the fourth current being different from each other.

24. A storage medium storing a program for testing a semiconductor circuit which includes:
a first fixed potential point;
a second fixed potential point;
a first switching section having a control terminal;
a second switching section having a control terminal;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the control terminal of the first switching section and the testing terminal,
the second switching section becoming ON and OFF in accordance with a potential difference applied between the control terminal of the second switching section and the testing terminal,
the first switching section and the first resistor element being serially connected between the first fixed potential point and the testing terminal,
the second switching section and the second resistor element being serially connected between the second fixed potential point and the testing terminal,
the program, causing a computer to carry out the steps of:
testing the first resistor element by measuring the resistance of the first resistor element in accordance with a first current and a second current, the first current being caused to flow through the testing terminal by applying a first voltage to the testing terminal such that the first switching section is turned ON and the second switching section is turned OFF, the second current being caused to flow through the testing terminal by applying a second voltage to the testing terminal such that the first switching section is turned ON and the second switching section is turned OFF, the first voltage and the second voltage being different from each other; and
testing the second resistor element by measuring the resistance of the second resistor element in accordance with a third current and a fourth current, the third current being caused to flow through the testing terminal by applying a first voltage to the testing terminal such that the second switching section is turned ON and the first switching section is turned OFF, the fourth current being caused to flow through the testing terminal by applying a fourth voltage to the testing terminal such that the second switching section is turned ON and the first switching section is turned OFF, the third voltage and the fourth voltage being different from each other.

25. A storage medium storing a program for testing a semiconductor circuit which includes:
a first fixed potential point;
a second fixed potential point;
a first switching section having a control terminal;
a second switching section having a control terminal;
a first resistor element, whose resistance is to be measured;
a second resistor element, whose resistance is to be measured; and
a testing terminal for measuring the resistance of the first resistor element and the resistance of the second resistor element,
the first switching section becoming ON and OFF in accordance with a potential difference applied between the control terminal of the first switching section and the testing terminal,
the second switching section becoming ON and OFF in accordance with a potential difference applied between the control terminal of the second switching section and the testing terminal,
the first switching section and the first resistor element being serially connected between the first fixed potential point and the testing terminal,
the second switching section and the second resistor element being serially connected between the second fixed potential point and the testing terminal,
the program, causing a computer to carry out the steps of:
testing the first resistor element by measuring the resistance of the first resistor element in accordance with a first voltage and a second voltage, the first voltage being applied to the testing terminal by causing a first current to flow through the testing terminal such that the first switching section is turned ON and the second switching section is turned OFF, the second voltage being applied to the testing terminal by causing a second current to flow through the testing terminal such that the first switching section is turned ON and the second switching section is turned OFF, the first current and the second current being different from each other; and
testing the second resistor element by measuring the resistance of the second resistor element in accordance with a third voltage and a fourth voltage, the third voltage being applied to the testing terminal by causing a third current to flow through the testing terminal such that the second switching section is turned ON and the first switching section is turned OFF, the fourth voltage being applied to the testing terminal by causing a fourth current to flow through the testing terminal such that the second switching section is turned ON and the first switching section is turned OFF, the third current and the fourth current being different from each other.
